(19) United States
(12) Patent Application Publication
(10) Pub. No.: US 2022/0082945 A1
(43) Pub. Date: Mar. 17, 2022

(54) SUBSTRATE HOLDER FOR USE IN A LITHOGRAPHIC APPARATUS AND A METHOD OF MANUFACTURING A SUBSTRATE HOLDER

(71) Applicant: ASML Netherlands B.V., Veldhoven (NL)

(72) Inventors: Andrey NIKIPELOV, Eindhoven (NL); Antonius Franciscus Johannes DE GROOT, Lierop (NL); Mariya NEKLYUDOVA, 's Hertogenbosch (NL)

(73) Assignee: ASML Netherlands B.V., Veldhoven (NL)

(21) Appl. No.: 17/418,719

(22) PCT Filed: Nov. 29, 2019
(86) PCT No.: PCT/EP2019/083027

§ 371 Date: Jun. 25, 2021

Related U.S. Application Data
(60) Provisional application No. 62/786,300, filed on Dec. 28, 2018.

(51) Int. Cl. G03F 7/20

(52) U.S. Cl. CPC G03F 7/707; G03F 7/70975; G03F 7/7095

(57) ABSTRACT

A method of producing a substrate holder for use in a lithographic apparatus, the substrate holder comprising a main body having a main body surface, wherein the method includes the steps of: coating at least part of the main body with a layer of a first coating material; and treating a plurality of discrete regions of the first coating material with laser irradiation to selectively convert said first coating material in said regions to a second coating material having a different structure or density.

### CROSS-REFERENCE TO RELATED APPLICATIONS

This application claims priority of U.S. application No. 62/786,300 which was filed on 28 Dec. 2018 and which is incorporated herein in its entirety by reference.

### FIELD

The present invention relates to substrate holders for use in a lithographic apparatus and methods of manufacturing substrate holders.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as “Moore's law”. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm.

In a lithographic apparatus the substrate to be exposed (which may be referred to as a production substrate) is held on a substrate holder (sometimes referred to as a wafer table). The substrate holder may be moveable with respect to the projection system. The substrate holder usually comprises a solid body made of a rigid material and having similar dimensions in plan to the production substrate to be supported. The substrate-facing surface of the solid body is provided with a plurality of projections (referred to as burls). The distal surfaces of the burls conform to a flat plane and support the substrate. The burls provide several advantages: a contaminant particle on the substrate holder or on the substrate is likely to fall between burls and therefore does not cause a deformation of the substrate; it is easier to machine the burls so their ends conform to a plane than to make the surface of the solid body flat; and the properties of the burls can be adjusted, e.g. to control the clamping of the substrate.

However, the burls of the substrate holder wear during use, e.g. due to the repeated loading and unloading of substrates. Uneven wear of the burls leads to unflatness of the substrate during exposure which can lead to a reduction of the process window and, in extreme cases, to imaging errors. Due to the very precise manufacturing specifications, substrate holders are expensive to manufacture so that it is desirable to increase the working life of a substrate holder.

Some substrate holders are provided with a diamond-like coating (DLC) on the main body, which is typically SiC or SiSiC. This DLC coating consists of 30-40% sp3-hybridized C atoms, with the rest being mainly sp2-hybridized C atoms and some H atoms. However, the wear, oxidation and unstable friction of the DLC-coated burls are believed to cause significant issues for substrate holder degradation. This is believed to be due to the high content of sp2-hybridized C atoms in the DLC.

Therefore it is desirable to coat the substrate holders or at least burls of the substrate holders with a coating such as diamond or other ultra-hard material. However, the available manufacturing techniques for diamond coating are not practical for substrate holders. In particular, diamond coatings are typically applied by an enhanced CVD process to a hot substrate (500-1200° C.). This is impractical for an assembled substrate holder as it causes significant thermal stress in the insulated electrodes, in the SiC or SiSiC main body and/or between the formed diamond and the ceramic main body. As a result, the substrate holders may warp and/or need considerable polishing to meet the flatness requirements. Further, it is difficult to spatially control the growth of the diamond coating.

### SUMMARY

An object of the present invention is to provide a substrate holder with a harder coating on distal ends of the burls, and a method of manufacturing a substrate holder which can produce such a coating.

It is a further object of the present invention to provide a substrate holder with burls which are selectively coated in order to adjust the properties of the burls, or the properties of different portions of a burl.

In an embodiment of the present invention there is provided a method of producing a substrate holder for use in a lithographic apparatus, the substrate holder comprising a main body having a main body surface, wherein the method includes the steps of: coating at least part of the main body with a layer of a first coating material; and treating a plurality of discrete regions of the first coating material with laser irradiation to selectively convert said first coating material in said regions to a second coating material having a different structure or density.

When embodiments of the invention refer to “producing” a substrate holder, this includes both the original production of a substrate holder and any other processes including the specified steps which modify, repair or otherwise treat a substrate holder to change its structure or properties.

In a further embodiment of the present invention there is provided a substrate holder for use in a lithographic apparatus and configured to support a substrate, the substrate holder comprising: a main body having a main body surface; a plurality of burls projecting from the main body surface, wherein: each burl has a distal end surface which is configured to engage with the substrate; the distal end surfaces of the burls substantially conform to a support plane and are configured for supporting the substrate; and the distal end surfaces of at least some of the burls have a first coating of diamond, cubic-BN, C3N4, a metal boride, Si3N4 or SiC or a material comprising at least two of: C, B, N, Si, and the inter-burl regions of the main body have a different coating or no coating.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 schematically depicts a lithographic apparatus;

FIGS. 2A-2C illustrate burls of substrate holders according to an embodiment of the present invention;

FIG. 3 shows a substrate holder according to an embodiment of the present invention;

FIG. 4 illustrates the processing of a surface of a burl of a substrate holder according to an embodiment of the present invention;

FIGS. 5A-5B illustrate burls of substrate holders according to an embodiment of the present invention;

FIG. 6A-6D show the steps in a process of repairing a substrate holder according to an embodiment of the present invention;

FIGS. 7A-7B illustrate burls of substrate holders according to an embodiment of the present invention;

FIGS. 8A-8E show the steps in a process of manufacturing a substrate holder according to an embodiment of the present invention; and

FIGS. 9A-9E show the steps in a process of manufacturing a substrate holder according to another embodiment of the present invention.

### DETAILED DESCRIPTION

In the present document, the terms “radiation” and “beam” are used to encompass all types of electromagnetic radiation, including ultraviolet radiation (e.g. with a wavelength of 436, 405, 365, 248, 193, 157, 126 or 13.5 nm). In particular, the “radiation” used for the conversion of material in the coating of a substrate holder or a burl of a substrate holder may be any type of electromagnetic radiation, including visible and infra-red.

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

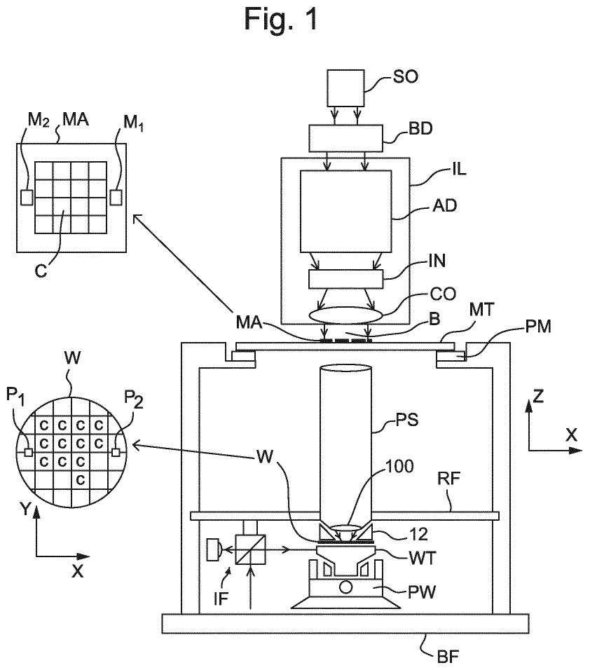

FIG. 1 schematically depicts a lithographic apparatus. The lithographic apparatus includes an illumination system (also referred to as illuminator) IL configured to condition a radiation beam B (e.g., EUV radiation or DUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a substrate holder) WT constructed to hold a substrate (e.g., a resist coated wafer) W and connected to a second positioner PW configured to accurately position the substrate support WT in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives the radiation beam B from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus may be of a type wherein at least a portion of the substrate W may be covered by an immersion liquid having a relatively high refractive index, e.g., water, so as to fill an immersion space 10 between the projection system PS and the substrate W—which is also referred to as immersion lithography. More information on immersion techniques is given in U.S. Pat. No. 6,952,253, which is incorporated herein by reference.

The lithographic apparatus may be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus may comprise a measurement stage (not depicted in FIG. 1). The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

In this specification, a Cartesian coordinate system is used. The Cartesian coordinate system has three axis, i.e., an x-axis, a y-axis and a z-axis. Each of the three axis is orthogonal to the other two axis. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

In a lithographic apparatus it is necessary to position the upper surface of a substrate to be exposed in the plane of best focus of the aerial image of the pattern projected by the projection system with great accuracy. To achieve this, the substrate is held on a substrate holder. The surface of the substrate holder that supports the substrate is provided with a plurality of burls whose distal ends are coplanar in a nominal support plane. The burls, though numerous, are small in cross-sectional area parallel to the support plane so that the total cross-sectional area of their distal ends is a few percent, e.g. less than 5%, of the surface area of a substrate. The burls are commonly conical in shape but need not be. The gas pressure in the space between the substrate holder and the substrate is reduced relative to the pressure above the substrate to create a force clamping the substrate to the substrate holder. Alternatively, the substrate holder is provided with a number of electrodes that can clamp conducting substrate using electrostatic pressure.

The burls serve several purposes. For example, if a contaminant particle is present on the substrate holder or the substrate, it is probable that it is not located at the location of the burl and therefore does not distort the substrate. In addition, it is easier to manufacture the burls so that their distal ends conform accurately to a flat plane than to manufacture a large area with very low flatness.

The burls of a substrate holder wear during use. The wear is generally uneven and therefore causes unflatness in the surface of substrates held by a worn substrate holder. When such wear becomes excessive it is necessary to repair or replace the substrate holder. Repair and replacement of the substrate holder are expensive, not only due to the cost of the repair process or the manufacture of a new substrate holder, but also due to the downtime of the lithographic apparatus that is required.

Embodiments of the present invention use pulsed laser-induced phase transition to change the structure and properties of a coating layer on the burls. Pulsed irradiation of the materials can allow relatively quick cooling of the irradiated material (after the pulse has finished) that permits or drives solidification into highly-crystalline forms which are desirable.

In particular embodiments, the laser-induced phase transition can be approximated as DLC->diamond, or as graphite->DLC->diamond. As a result of the laser-induced phase transition(s), there is a significant increase in the proportion of sp3-hybridized C in the coating layer at the expense of sp2-hybridized C during quenching of hot (eg metallic, liquid) C (in some cases at ˜4000 C). In certain embodiments, the resulting coating layer has over 90% sp3 C, preferably over 95% sp3 C, more preferably 100% sp3 C. In this specification “diamond” is used to refer to any material with a content of over 90% sp3-hybridized C atoms.

Further, whilst the present description will discuss mainly the effects and processes used to create a diamond coating layer on the burls, other coatings, based on ultra-hard materials may offer even better performance than diamond for particular coatings on the substrates. For example, the principles of the embodiments described herein are equally applicable to other ultra-hard materials such as cubic-BN, C3N4, metal borides, Si3N4 and SiC or a material comprising at least two of: C, B, N, Si. In particular, cubic-BN has comparable mechanical properties to diamond, but in some cases can be more robust chemically.

In the case of BN, the processes may be used to cause a transition of hBN or high-energy ion implantation produced, disordered BN to c-BN. The initial coating layer in these arrangements may be a high compressive stress layer, produced by high energy ion implantation (which will likely result in a mix of h-BN and c-BN or amorphous BN).

The improved coating layer may be used for a variety of purposes and in a variety of processes within the manufacture of the substrate holder, in addition to the general objective of increasing the sp3 C content in DLC.

For example, the processes may be used to provide a template for diamond film growth for enhanced CVD, to repair burls with diamond coating, and/or to change the crystallinity of high sp3-content DLC (for example ta-C coatings based on carbon implanted at high energies (e.g. 10-100 eV)).

For deep ultra-violet (DUV) irradiation of Ta—C (tetrahedral Carbon), the effects of the irradiation are believed to be explained by either: a) epitaxial crystallization of under-cooled C, starting from the crystalline (and cold) interface with the lattice of the underlying material of the main body and/or b) by relaxation of the compressive stress via recrystallization that densifies the layer regions affected.

In certain embodiments is desirable to use wavelengths which improve and preferably maximize the ratio of extinction coefficients of the coating and the main body k_{coating}/k_{main body} in order to melt only the original coating, whilst keeping the substrate relatively cold (and therefore crystalline).

In other embodiments the incident fluence may be tuned (taking account of extinction in both layers) such that the main body temperature stays below its melting point, whilst the temperature of the coating exceeds or at least approaches its melting point.

In some embodiments the substrate should also be sputtered or treated with H plasma to remove native oxide and expose crystallites with well-matched lattices (e.g. SiC) before application of the original (untreated) coating containing carbon.

Based on the phase diagram of Carbon and BN (dP/dT<0), fs pulse irradiation is considered to be beneficial in some embodiments since the electron-hole plasma (produced due to high fluence irradiation) is compressed by the absorbed photon momentum and the resulting pressure transferred to the material lattice can drive almost instantaneous melting.

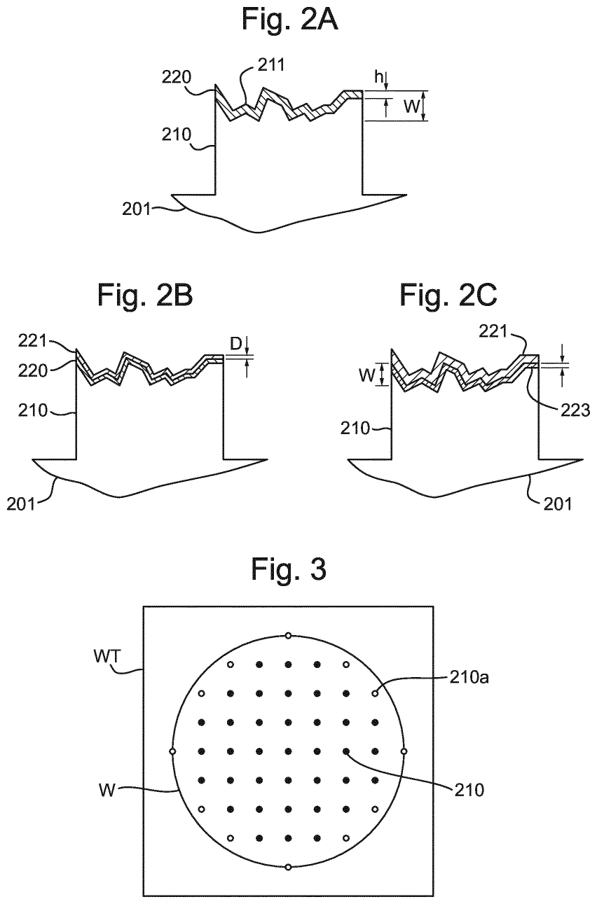

FIG. 2 shows, schematically, the stages in a method according to a first embodiment of the present invention. FIG. 2A shows a typical existing burl 210 extending upwards from the main body 201 of a substrate holder WT. The burl 210 has a DLC (or Ta—C) coating 220 on the distal end surface 211. The coating 220 has a conformal typical thickness h which is less than the burl grain roughness W.

The burls 210 of the substrate holder are then subjected to pulsed laser irradiation (which may be a single pulse or a multi-pulse sequence). Preferably the laser used is a DUV/excimer laser or an IR laser with fluence in the range of ˜0.1-1 J/cm2. Alternatively the laser may be a fs/ps laser with fluence per flash of ˜0.5-50% of the ablation threshold.

Whilst the irradiation can be carried out in any atmosphere, it is preferably done in a vacuum or near vacuum to reduce the risk of oxidation during the induced heating/cooling.

This irradiation causes the DLC coating 220 to at least partially convert to nano/micro-scale diamonds and/or diamond onions (Fullerean diamond). FIG. 2B shows an arrangement in which part 221 of the DLC coating 220 has been converted to diamond with the material of the main body of the burl being unaffected. FIG. 2C shows an alternative arrangement in which the coating is fully converted to diamond 221 and a layer 223 of the main body of the burl has also been affected, for example, by recrystallization and/or being inter-diffused with carbon from the coating layer 220.

The use of laser-irradiation of the DLC coating 220 means that conversion of the DLC coating 220 can be spatially controlled to a high degree of accuracy. For example, the irradiation can be controlled such that conversion only takes place on the distal end surface 211 of the burls 210. Furthermore, the spatial control means that different burls or groups of burls can be treated differently, which allows burls or groups of burls to be treated differently across the substrate holder depending on the desired outcome.

A further or alternative effect of the selective irradiation in this method is that it allows the formation of diamond only in specific areas (and in particular can ensure that the diamond is produced on the distal end surface of the burls and not between burls). This can prevent the introduction of additional global stress to the substrate holder and thus can avoid warping the substrate holder which would necessitate further planarization treatment.

Further, by limiting the stressed (diamond) coating to a single burl, the robustness of that coating to peeling/chipping off and cracking can be improved.

Although the process of this embodiment has been described in relation to the manufacture of substrate holders, it can also be used for the repair and reconditioning of existing substrate holders.

A further potential advantage of this process is that the properties of the laser illumination (pulse frequency, pulse length, pulse energy or wavelength etc.) can be selected (and varied) on a burl-by-burl basis. This can allow the properties of individual burls (or groups of burls) to be varied across the substrate holder. By appropriate selection of the illumination criteria, various properties such as the friction coefficient, contact spot (the burl to wafer contact area), etc. of the distal end surfaces of the burls can be adjusted for each burl (or group of burls). For example burls near the edge of the of the substrate holder, which suffer the most wear due to slip, can be made harder than burls in the center of the substrate holder. The burls can alternatively or additionally adjusted to improve or optimize wafer load grid (WLG), WLG is a distortion in overlay, related to unflatness of the wafer during clamping and finite friction coefficient between burls and wafer. This is shown schematically in FIG. 3, where the edge burls 210a have been treated differently to the other burls 210.

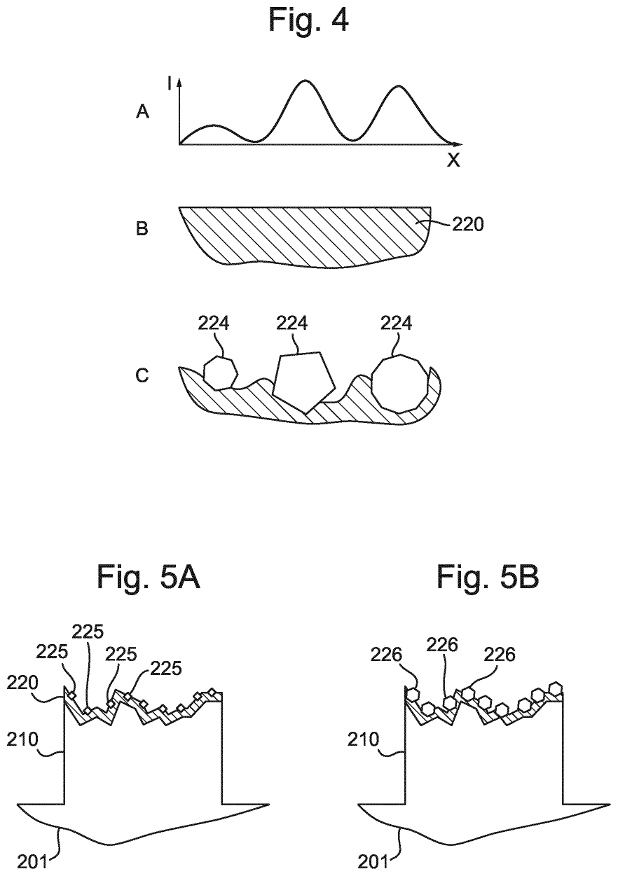

As well as selecting and varying the properties of the laser illumination between burls, the illumination profile within each burl can also be varied, for example by interference and/or intensity variation. This can allow the tuning of the crystallization pattern or fidelity within the coating on each burl and, as a result, can improve or optimize the stress or adhesion of the coating, for example by reducing/increasing the diamond phase thickness towards the edges of the burl. FIG. 4 shows, schematically how this may be achieved. The graph in FIG. 4A shows the variation in laser intensity spatially across the surface of the coating 220 of the distal end surface of the burl shown in FIG. 4B. FIG. 4C shows the resulting effects on the coating in creating a controlled (in terms of size and position) distribution of diamond (or high sp3 content) microcrystals 224 within the DLC coating 220.

Although the coating 220 is shown in FIG. 4 as being flat, the actual surface will not be so. However, by use of intensity variation, the position and size of the microcrystals formed can be decoupled from the roughness of the distal end surface. Control of the crystallization seed is possible down to a few microns using a DUV/visible laser with a reasonable numerical aperture.

In a development of the above embodiment, the chances of crystallization into diamond following the laser illumination are improved by applying a surface treatment of the substrate prior to the initial deposition of the DLC coating. This may be done in order to change the interface, for example by removing oxides from the surface of the main body (SiC and SiSiC material is normally covered in a thin layer of up to a few 10s of nm of native oxide at the exposed distal end surface of the burl). This treatment may use H2 plasma or non-depositing CxHy plasma or sputtering noble gas plasma.

FIG. 5 shows, schematically, the stages in a method according to a second embodiment of the present invention. In this embodiment the burls 210 of a substrate holder are first coated with a thin layer 220 of DLC (i.e. a layer which has a thickness less that the desired thickness of the finished coating). After coating, the burls are exposed to pulsed laser irradiation. Preferably this is a DUV/excimer laser with a fluence of ˜0.1-1 J/cm2 or a fs/ps laser with a fluence per flash of ˜0.5-50% of the ablation threshold. This creates seed nano-diamonds 225 on the distal end surface of the burl as shown in FIG. 5A. This seeded substrate can then be used to grow the diamond crystals to create a coating 226 of the desired thickness, as shown in FIG. 5B. This growth step may be, for example, using moderate temperature enhanced CVD growth and leads to preferential growth on the existing nano-diamond seeds.

By tuning the irradiation properties and/or the initial thickness and/or the composition of the coating layer 220 properties of the seeding such as the surface concentration, the mean size and the size distribution of the diamond can be controlled. In turn this can allow control of the finished diamond coating and, as with the first embodiment above, the properties can be tuned or adjusted between burls or globally in order to adjust macroscopic properties such as friction coefficients, contact areas and wear rates.

As the diamond seeds are created only where there is irradiation on the distal end surface of the burl, it is possible to avoid creating seeds between burls. This means that the subsequent diamond growth step does not form a universal diamond coating (or the formation of such a coating is reduced or delayed) and so the additional stress and the associated warping of the substrate holder experienced when a universal diamond coating is applied can be avoided.

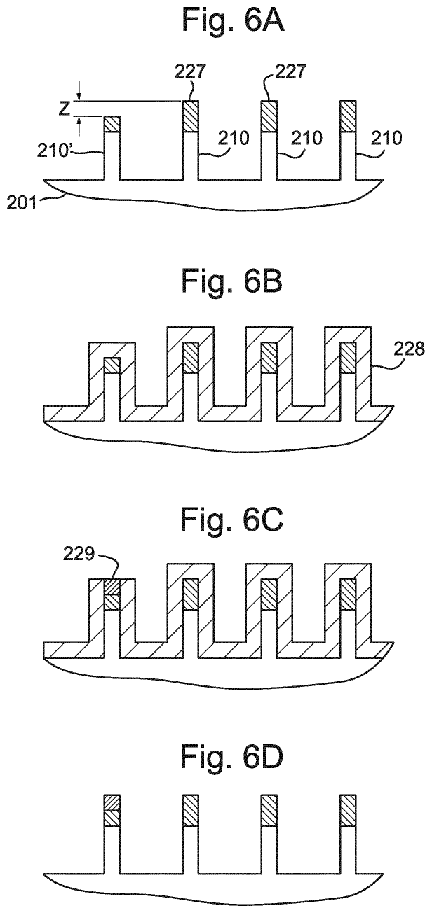

FIG. 6 shows, schematically, how a method according to an embodiment of the present invention can be used to repair burls on a substrate holder. As noted above, some of the burls of a substrate holder, typically those at the wafer edges, wear much quicker than others. It is therefore beneficial to add to the thickness of the existing diamond coating on such burls periodically in order to bring their thickness (and height) back to the original levels. As the addition/repair process can be targeted on a burl-by-burl basis, the process can be used to treat only the worn burls and thus can avoid the need to recondition the entire substrate holder by stripping it of coating and re-coating it, which is significantly more time-consuming and expensive.

FIG. 6A shows part of a substrate holder 200 where the outer burl 210′ has been worn through use such that a thickness z of the coating layer 227 has been removed. To carry out the repair, first a layer 228 of carbon is deposited via evaporation or sputtering as amorphous graphite on at least some burls 210, including the burls 210′ which are to be repaired, as shown in FIG. 6B. Ideally the layer 228 of graphite should match or exceed z in thickness. This process is similar to SEM/TEM sample preparation and thickness control is possible at nm scales.

Selected burl(s) 210′ whose surface coating is to be repaired are then exposed to laser irradiation (in the manner described generally in the previous embodiments) and the graphite layer on the burl(s) 210′ is converted to diamond, forming an additional layer 229 of diamond, as shown in FIG. 6C.

The substrate holder is then exposed to atomic hydrogen (e.g. from a hydrogen radical generator) or oxidizing selective etchant which removes the remaining graphite 228 from the areas which have not been exposed to the laser and remain untreated. Alternatively, the substrate holder may be subjected to CMP (chemo-mechanical polishing) to remove the remaining graphite. The diamond coatings (both new and old) of the burls are mostly or totally unaffected by this and so the burl 210′ is repaired without notable effect on the remainder of the substrate holder or on the other burls, as shown in FIG. 6D.

In further embodiments of the present invention, substrate holder s which already have high sp3 DLC coatings applied by other methods can be improved. The high sp3 content DLC coatings of existing substrate holder s (produced by methods other than those of the present invention) may exhibit good mechanical properties but are believed to be inferior in terms of friction and/or contact spot. This may be due to the coatings being too conformal to the coarse-grained main body of the substrate holder or because they contain a mixture of crystalline and amorphous phases. These coatings can thus be improved by applying methods such as those in the previous embodiments to selectively irradiate the existing coating and re-crystallize it into nano- or micro-diamonds.

Other Ta—C coatings which have been applied via high-energy ion deposition (involving implantation at around 10-100 eV) tend to have very high compressive stress and can thus be fragile and brittle. To avoid this, such coatings are often applied in a layer structure with sp2-rich phases to allow some degree of relaxation. However, selective laser irradiation as described in the previous embodiments can provide an alternative way to relax such structures and so avoid the need to introduce the sp2 phase, which is detrimental to the properties of such materials.

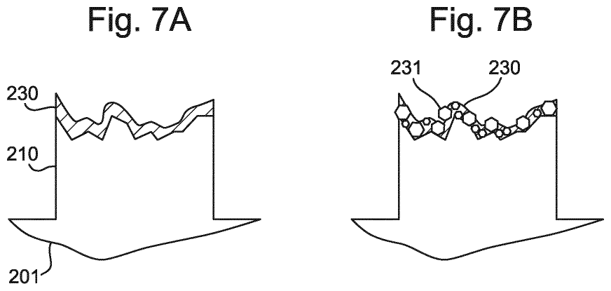

FIG. 7A shows a burl 210 with a Ta—C coating 230 which has been applied to the distal end surface of the burl by ion implantation. The burl is then subjected to laser irradiation. This has two effects. Firstly, recrystallization causes micro- and nano-diamonds 231 to form in the coating which provide improve wear resistance and/or lower friction or contact spot. Secondly, the non-crystallized parts of the coating 230 may be relaxed and the stress in these areas reduced which can improve coating adhesion.

As with the embodiments described above, in addition to the general benefits form such recrystallization, it is possible to control the topology and/or crystallinity of the coating 230, and it is also possible to tune the parameters of different burls or groups of burls to adjust, for example, their friction coefficient or contact spot.

In further embodiments of the present invention, the selective laser irradiation of coating layers on the burls may be used to provide local structuring on the burls such as nano-waves and micro-structuring. This enables greater control over the distal end surface of the burl in order to achieve the desired burl-substrate contact pressure and/or friction coefficient. Creating cavities furthermore leaves free spaces open to absorb contamination coming from the back side of the substrate.

In further embodiments of the present invention, the laser-induced phase conversion may be used to correct the burl surface by reconditioning the surface after a cleaning process has been carried out. The cleaning may change a top portion of hard coating chemically (for example introduce a less stable phase) or mechanically (for example create nano-cracks or voids). Then laser irradiation can reverse such changes, since the melting and re-solidification tend to remove imperfections. In case of DLC or diamond coating the cleaning processes may be the sequence of partial removal of material from the distal end surface of the burl by oxidation (which may be laser-induced e.g. with a DUV laser), followed by polishing to remove ashes and dirt sitting on top of the graphene/graphite that the diamond surface converts to before burning, followed by repair to convert the graphite back to diamond (optionally with an intervening step to add further graphite prior to that conversion). Alternatively, this may be by in-vacuum thermal release of debris during which the collateral melting/solidification into diamond (from underlying diamond that is not melted) which may push the dirt out.

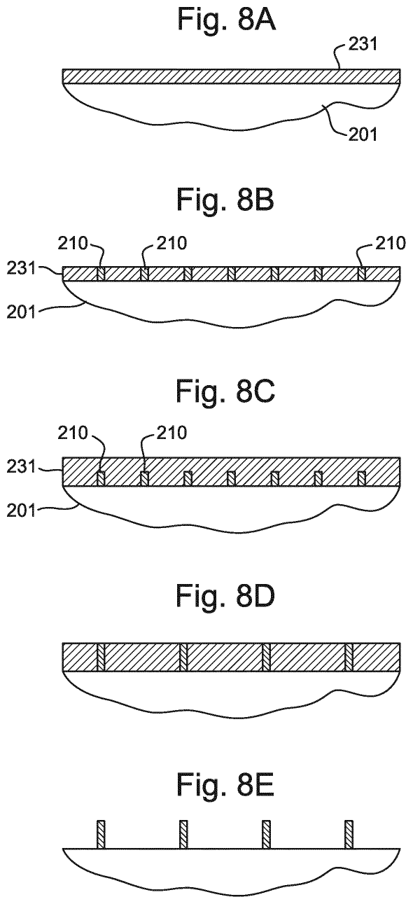

In further embodiments of the present invention similar processes to those described in relation to the above embodiments may be used to create the burls themselves on a flat substrate holder coated with either DLC or graphite. FIG. 8 shows the steps in one such process.

First a graphite (or a-DLC) layer 231 is formed on the main body 201 as shown in FIG. 8A. This is selectively and locally converted to diamond (or higher sp3 DLC) via laser irradiation as previously described to form burls 210 (FIG. 8B). The process may be repeated step-wise to grow the burls 210 by applying further layers of graphite (FIG. 8C) and treating these with further localized irradiation to grow the burls (FIG. 8D). At the end of the growth steps, the excess graphite is removed via H* exposure (or oxidation or other selective etch processes) to leave a substrate holder with a plurality of diamond burls 210 (FIG. 8E).

This step-wise approach to growing burls can be virtually stress-free as most of the stresses in the previous layer are removed via re-crystallization before the subsequent layer is applied. It can also create burls which are more uniform than those produced by other processes as the irradiation affects the full thickness of the new layer.

By tuning the laser properties, a particular profile or crystallinity may be provided within the burl (in particular in the final layer). Further, by tuning the laser properties and/or the thickness of the initial graphite layer 231, the interface with the main body 201 can be reinforced in the first laser-treatment step as a result of laser-induced inter-diffusion.

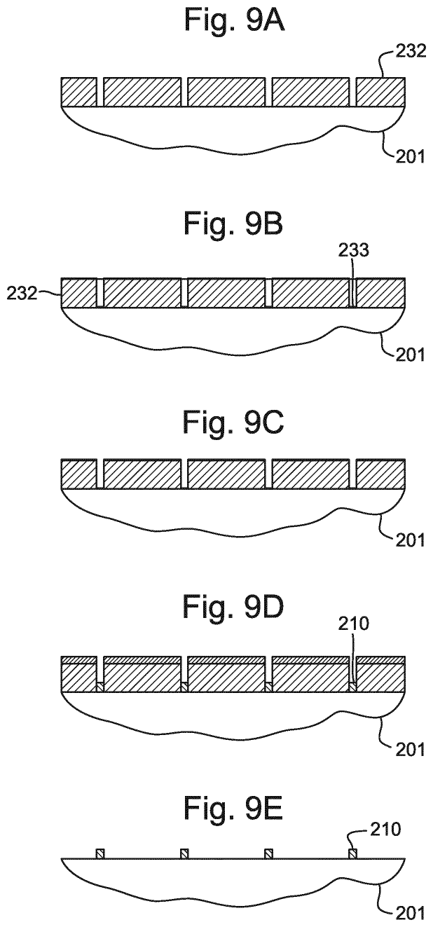

FIG. 9 shows the steps in an alternative process, in which a Ta—C (or, less preferably, DLC or graphite) coating is applied to a main body 201 of the substrate holder through sacrificial mask 232 provided with holes 233 corresponding to the desired location of future burls (FIG. 9A). The coating deposited in holes 233 is periodically treated with laser to change density or crystallinity of the burl, portion of the final height at a time. The sacrificial mask is at least as thick as the desired burl height. The sacrificial mask preferably is based on or at least is coated with carbon (graphite), or is polymer based to avoid contamination of the growing burl with alien material that may be collaterally sputtered during Ta—C application (that is based on energetic ions, incident on the target).

By using laser ablation with a substrate bias (for example as a method to apply Ta—C) and/or enhanced CVD/PVD (for example as a method to apply DLC) or evaporation (for example as a method to apply graphite) the burls 210 are grown in the holes 233, a portion of the final height at a time and periodically irradiated with highly localized laser irradiation which is directed only at the burls (as described in previous embodiments) to induce re-crystallization (FIGS. 9B & 9C & 9D) and diamond formation. This step-wise growth relieves stress and reinforces the growing crystals on the burls 210. The burls are grown in an iterative process of deposition/irradiation. The irradiated regions may be smaller than the holes 233, to provide a mechanically weak transition between mask and burl, to ease subsequent mask removal.

In the final step the remaining sacrificial mask is removed, optionally provided with a selective etch (H* or oxidizing plasma) or in a chemo-mechanical polishing to reduce/weaken adhesion between finished burls. The burls 210 may be protected by a removable patterned layer during the etching to further improve selectivity and to arrive at the finished substrate holder (FIG. 9E).

In further embodiments of the present invention, similar methods to those described in the embodiments above can be used to produce clamps for substrates and reticles. For these components, control of the process temperature is even more important due to the glass ceramics involved.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains one or multiple processed layers.

Although specific reference may have been made above to the use of embodiments of the invention in the context of optical lithography, it will be appreciated that the invention may be used in other applications.

While specific embodiments of the invention have been described above, it will be appreciated that the invention may be practiced otherwise than as described.

The descriptions above are intended to be illustrative, not limiting. Thus, it will be apparent to one skilled in the art that modifications may be made to the invention as described without departing from the scope of the claims set out below.

1.-16. (canceled)

17. A method of producing a substrate holder for use in a lithographic apparatus, the substrate holder comprising a main body having a main body surface, the method comprising:
coating at least part of the main body with a layer of a first coating material comprising carbon, and
treating a plurality of discrete regions of the first coating material with laser irradiation to selectively convert the first coating material in the regions to a second coating material having a different structure or density, and
wherein a carbon content of the second coating material is more than 90% sp3-hybridized carbon.

18. The method of claim 17, wherein the substrate holder further comprises a plurality of burls projecting from the main body surface and each having a distal end surface configured to engage with the substrate, and wherein:
the coating coats at least the distal end surface of a plurality of the burls with a layer of the first coating material, and
the treating treats at least the plurality of discrete regions of the distal end surfaces with the laser irradiation.

19. The method of claim 18, wherein:
the method is a method of repairing an existing substrate holder in that one or more of the burls has been worn down at the distal end surface, and
the coating and treating are configured to coat and treat the distal end surface of the worn down burls.

20. The method of claim 17, wherein the coating and treating are performed repeatedly to build up the discrete regions to form burls projecting from the main body of the substrate holder.

21. The method of claim 17, wherein:
the first coating material is a mask having a plurality of holes in it, and
the treating treats regions in the holes and is repeated to form burls in the holes.

22. The method of claim 17, further including removing the untreated areas of the first coating material.

23. The method of claim 17, wherein the second coating material is harder than the first coating material.

24. The method of claim 17, wherein the treating applies different laser irradiation to different ones of the discrete regions, such that at least one property of the second coating material differs between the regions.

25. The method of claim 24, wherein the treating applies different laser irradiation to one or more burls in an outer region of the substrate holder compared to one or more burls in an inner region of the substrate holder, such that the second coating material of the burls in the outer region is harder and/or thicker and/or has different coefficient of friction than the second coating material of the burls in the inner region.

26. The method of claim 17, wherein the discrete regions include distal end surfaces of a plurality of burls projecting from the main body surface.

27. The method of claim 17, wherein the discrete regions include discrete regions on a distal end surface of a single burl.

28. The method of claim 17, wherein the treating creates a plurality of seed crystals of the second coating material and further including:
growing the second coating material on the seed crystals.

29. A substrate holder for use in a lithographic apparatus and configured to support a substrate, the substrate holder comprising:
a main body having a main body surface;
a plurality of burls projecting from the main body surface, wherein:
each burl has a distal end surface that is configured to engage with the substrate, and
the distal end surfaces of the burls substantially conform to a support plane and are configured for supporting the substrate,
the distal end surfaces of at least some of the burls have a first coating comprising carbon,
the carbon comprises more than 90% sp3-hybridized carbon, and
the inter-burl regions of the main body have a different coating or no coating.

30. The substrate holder of claim 29, wherein at least one property of the first coating on the distal end surfaces of one of the burls differs from the property of the first coating on another of the burls.

31. The substrate holder of claim 29, wherein at least one property of the first coating on the distal end surface of a single one of the burls differs across the distal end surface of that burl.
